(19) United States
(12) Patent Application Publication
(10) Pub. No.: US 2005/0126484 A1
(43) Pub. Date: Jun. 16, 2005

(54) Edge flow faceplate for improvement of CVD film properties

(75) Inventors: Maosheng Zhao, Santa Clara, CA (US); Lun Tsuei, Mountain View, CA (US); Juan Carlos Rocha-Alvarez, Sunnyvale, CA (US); Tom K. Cho, Palo Alto, CA (US)

Correspondence Address: Applied Materials, Inc.;Legal Affairs Department, Patent Counsel, M/S 2061, P.O. Box 450A, Santa Clara, CA, 95052, US

(73) Assignee: APPLIED MATERIALS, INC., A Delaware corporation, Santa Clara, CA (US)

(21) Appl. No.: 11/013,124

(22) Filed: Dec. 15, 2004

Related U.S. Application Data
(60) Provisional application No. 60/529,819, filed on Dec. 15, 2003.

(51) Int. Cl. C23C 16/00

(52) U.S. Cl. 118/715; 427/248.1

(57) ABSTRACT

Embodiments in accordance with the present invention relate to apparatuses and methods distributing processing gases over a workpiece surface. In accordance with one embodiment of the present invention, process gases are flowed to a surface of a semiconductor wafer through a substantially circular gas distribution showerhead defining a plurality of holes. A first set of holes located at the center of the faceplate, are arranged in a non-concentric manner not exhibiting radial symmetry. This asymmetric arrangement achieves maximum density of holes and gases distributed therefrom. To compensate for nonuniform exposure of the wafer edges to gases flowed from the first hole set, the faceplate periphery defines a second set of holes arranged concentrically and exhibiting radial symmetry. Processing substrates with gases flowed through the first and second sets of holes results in formation of films exhibiting enhanced uniformity across center-to-edge regions.

### CROSS-REFERENCE TO RELATED APPLICATION

The instant U.S. nonprovisional patent application claims priority to U.S. provisional patent application No. 60/529,819, filed Dec. 15, 2003, which is incorporated by reference herein for all purposes.

### BACKGROUND OF THE INVENTION

Incorporated by reference herein for all purposes is U.S. Pat. No. 4,854,263, which describes plasma-enhanced chemical vapor deposition (PECVD) of materials such as silicon nitride, silicon oxide, and silicon oxynitride; the use of parallel plate PECVD reactors for depositing these materials; and, in particular, to a gas inlet manifold for a parallel plate reactor and a method of using the manifold and the reactor for depositing these materials at a high rate and for depositing silicon nitride and silicon oxynitride without using high-hydrogen content gases such as ammonia.

As described at length therein, U.S. Pat. No. 4,854,263 describes a gas inlet manifold faceplate the plate having a plurality of apertures, and each aperture comprising an outlet at the chamber or processing side of the plate and an inlet counterbore spaced from the processing side, with the outlet being larger than the inlet for enhancing the dissociation and reactivity of the gas. The aperture can be configured in any of a number of preferably concave cross-sectional configurations including parabolic or hyperbolic cross-sections or the presently preferred conical cross-section.

In still another aspect, the gas inlet apertures may be densely patterned as an array of overlapping/interlocking face-centered hexagons. An individual aperture defines an edge of one associated hexagon and is also at the center of a second associated hexagon. This dense configuration promotes uniform high rate deposition without patterns, streaks or other non-uniformities.

While effective to chemical vapor deposit materials on the surface of a substrate, it has been recognized that certain chemical vapor deposited films, particularly those containing carbon, may exhibit a reduced rate of deposition on edge portions. This difference in deposition rate at edge portions may make the resulting uniformity of the deposited film difficult to control. Accordingly, there is a need in the art for apparatuses and methods allowing for chemical vapor deposition of material having greater uniformity characteristics at substrate edge portions.

### SUMMARY OF THE INVENTION

Embodiments in accordance with the present invention relate to apparatuses and methods distributing processing gases over a workpiece surface. In accordance with one embodiment of the present invention, process gases are flowed to a surface of a semiconductor wafer through a substantially circular gas distribution showerhead defining a plurality of holes or apertures. A first set of holes located at the center of the faceplate, are arranged in a non-concentric manner not exhibiting radial symmetry. This asymmetric arrangement achieves maximum density of orifices and gases distributed therefrom. To compensate for nonuniform exposure of the wafer edges to gases flowed from the first hole set, the faceplate periphery defines a second set of holes arranged concentrically and exhibiting radial symmetry. Processing substrates with gases flowed through the first and second sets of holes results in formation of films exhibiting enhanced uniformity across center-to-edge regions.

An embodiment of an apparatus in accordance with the present invention comprises walls enclosing a process chamber, a wafer susceptor positioned within the chamber, and a first exhaust conduit in fluid communication with the chamber. A processing gas source is in fluid communication with the chamber through a substantially circular gas distribution showerhead. The gas distribution showerhead comprises a first set of holes positioned in a central showerhead region asymmetric to a radius of the showerhead, and a second set of holes positioned in a peripheral showerhead region symmetric to the radius.

An embodiment of a method in accordance with the present invention for depositing material on a semiconductor substrate, comprises, flowing processing gases to a central portion of a substrate through a first set of non-radially symmetrical holes present in a central portion of a substantially circular gas distribution faceplate. The processing gases are flowed to an edge portion of the substrate through a second set of radially symmetrical holes present in a peripheral portion of the substantially circular gas distribution faceplate.

These and other embodiments of the present invention, as well as its features and some potential advantages are described in more detail in conjunction with the text below and attached figures.

### BRIEF DESCRIPTION OF THE DRAWINGS

FIG. 1A is a simplified cross-sectional view of an exemplary CVD system.

FIG. 1B shows an exploded, perspective view of the CVD system of FIG. 1A.

FIG. 1C shows another exploded, perspective view of the CVD system of FIG. 1A.

FIG. 2 shows a simplified plan view of the underside of one embodiment of a gas distribution showerhead in accordance with the present invention.

FIG. 2A is a simplified schematic view illustrating the non-concentric arrangement of the first set of orifices of the showerhead of FIG. 2.

FIG. 2B is a simplified schematic view illustrating the concentric arrangement of the second set of orifices of the showerhead of FIG. 2.

FIG. 3A shows a simplified cross-sectional view of an orifice from the first set shown in the gas distribution showerhead of FIG. 2.

FIG. 3B shows a cross-sectional view of an orifice from the second set shown in the gas distribution showerhead of FIG. 2.

FIG. 4A plots refractive index and thickness of a BLOk™ nitrogen-containing barrier film deposited utilizing a conventional faceplate having only non-radially oriented holes.

FIG. 4B plots refractive index and thickness of a BLOk™ nitrogen-containing barrier film deposited utilizing a faceplate featuring non-radially oriented holes extended to cover a larger area than the faceplate of FIG. 4A.

FIG. 4C plots refractive index and thickness of a BLOk™ nitrogen-containing barrier film deposited utilizing a faceplate combining radially-oriented holes with the number of non-radially oriented holes of the conventional faceplate.

FIG. 4D plots refractive index and thickness of a BLOk™ nitrogen-containing barrier film deposited utilizing a faceplate combining radially-oriented holes with the extended number of non-radially oriented holes of the faceplate of FIG. 4B.

FIG. 5A shows the axial velocity exhibited by a simulated flow of gas through a first set of holes of a conventional faceplate design.

FIG. 5B shows the pressure drop exhibited by a simulated flow of gas through a first and second set of holes of an embodiment of a faceplate design in accordance with the present invention.

### DETAILED DESCRIPTION OF THE INVENTION

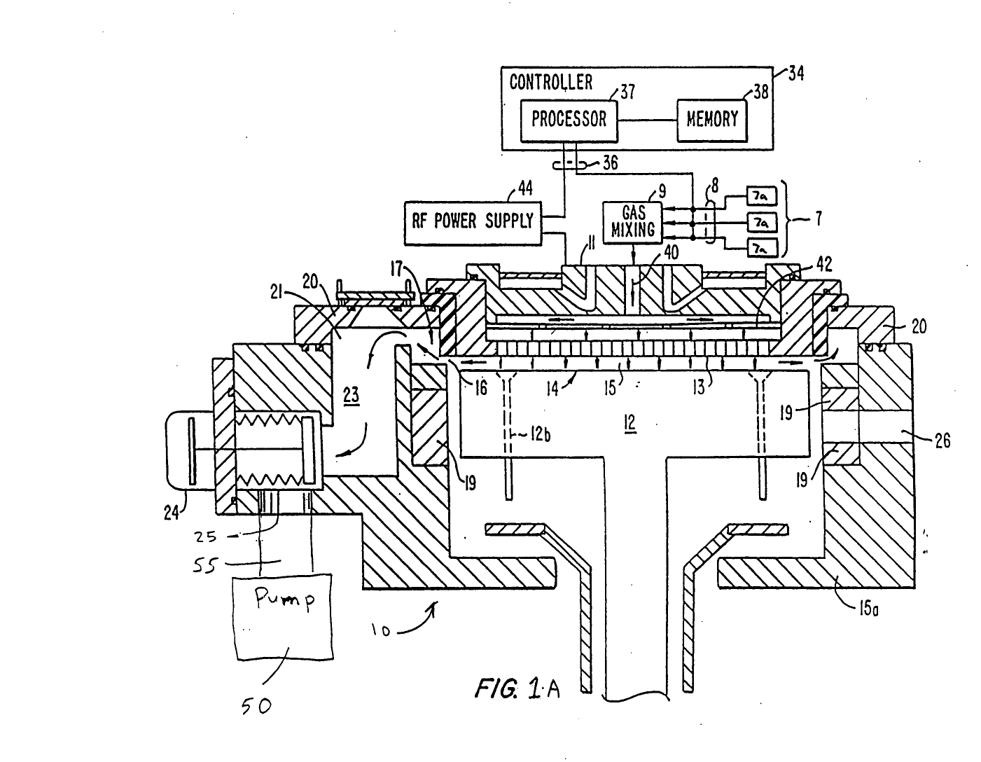

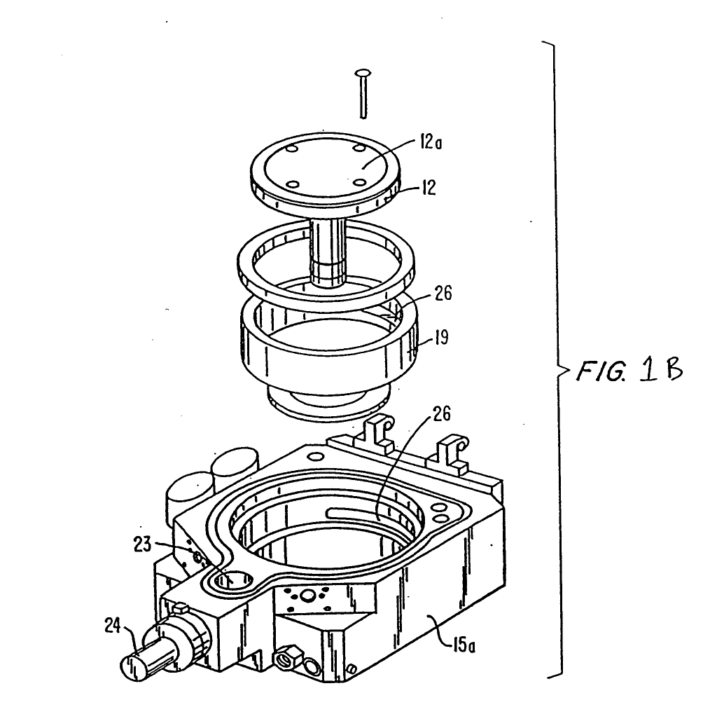

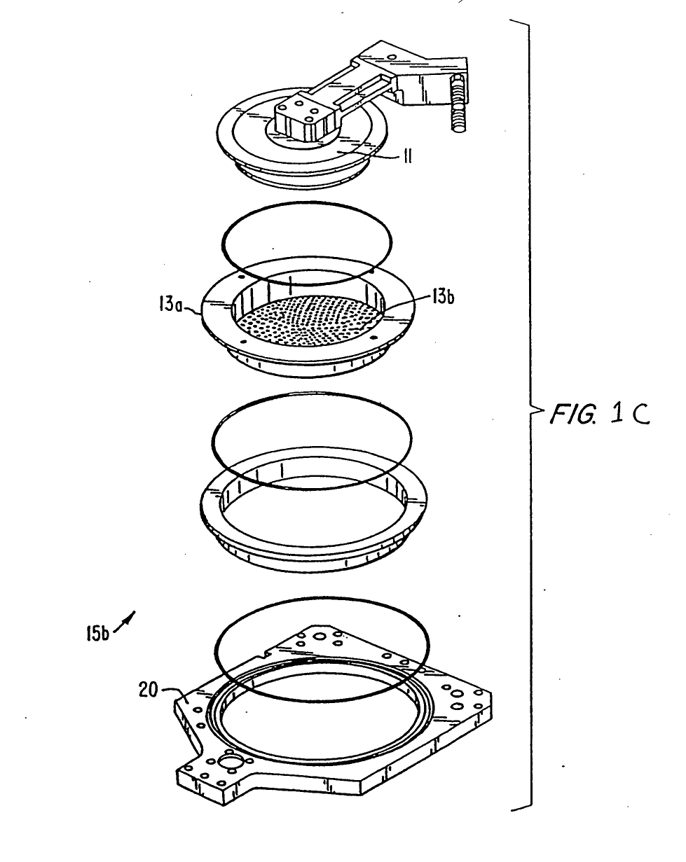

One suitable CVD apparatus in which the method of the present invention can be carried out is shown in FIG. 1A, which is a vertical, cross-sectional view of a CVD system 10, having a vacuum or processing chamber 15 that includes a chamber wall 15a and chamber lid assembly 15b. Chamber wall 15a and chamber lid assembly 15b are shown in exploded, perspective views in FIGS. 1B and 1C.

CVD system 10 contains a gas distribution manifold 11 for dispersing process gases to a substrate (not shown) that rests on a heated pedestal 12 centered within the process chamber. During processing, the substrate, for example, a semiconductor wafer, is positioned on a flat (or slightly convex) surface 12a (FIG. 1B) of pedestal 12. The pedestal can be moved controllably between a lower loading/off-loading position (not shown) and an upper processing position (shown in FIG. 1A) closely adjacent to manifold 11. A centerboard (not shown) includes sensors providing information on the position of the wafers.

Deposition and carrier gases are introduced into chamber 15 through holes 13b (FIG. 1C) of a flat, circular gas distribution faceplate 13a. More specifically, deposition process gases flow into the chamber through the inlet manifold 11 (indicated by arrow 40 in FIG. 1A), through a conventional perforated blocker plate 42 and then through holes 13b in gas distribution faceplate 13a.

Before reaching the manifold, deposition and carrier gases are input from gas sources 7a through gas supply lines 8 of gas delivery system 7 (FIG. 1A) into a mixing system 9 where they are combined and then sent to manifold 11. Generally, the supply line for each process gas includes (i) several safety shut-off valves (not shown) that can be used to automatically or manually shut-off the flow of process gas into the chamber, and (ii) mass flow controllers (also not shown) that measure the flow of gas through the supply line. When toxic gases (for example, ozone or halogenated gas) are used in the process, the several safety shut-off valves are positioned on each gas supply line in conventional configurations.

The deposition process performed in CVD system 10 can be either a thermal process or a plasma-enhanced process. In a plasma-enhanced process, an RF power supply 44 applies electrical power between the gas distribution faceplate 13a and the pedestal so as to excite the process gas mixture to form a plasma within the cylindrical region between the faceplate 13a and the pedestal, referred to as the “reaction region.” Constituents of the plasma react to deposit a desired film on the surface of the semiconductor wafer supported on pedestal 12. RF power supply 44 is a mixed frequency RF power supply that typically supplies power at a high RF frequency (RF₁) of 13.56 MHz and at a low RF frequency (RF₂) of 360 KHz to enhance the decomposition of reactive species introduced into the vacuum chamber 15. In a thermal process, RF power supply 44 would not be utilized, and the process gas mixture thermally reacts to deposit the desired films on the surface of the semiconductor wafer supported on pedestal 12, which is resistively heated to provide energy for the reaction.

During a plasma-enhanced deposition process, the plasma heats the entire process chamber 10, including the walls of the chamber body 15a surrounding the exhaust passageway 23 and the shut-off valve 24. When the plasma is not turned on or during a thermal deposition process, a hot liquid is circulated through the walls 15a of the process chamber to maintain the chamber at an elevated temperature. Fluids used to heat the chamber walls 15a include the typical fluid types, i.e., water-based ethylene glycol or oil-based thermal transfer fluids. This heating beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

The remainder of the gas mixture that is not deposited in a layer, including reaction products, is evacuated from the chamber by a vacuum pump 50 connected to the exhaust passageway 23 by foreline 55. Specifically, the gases are exhausted through an annular, slot-shaped orifice 16 surrounding the reaction region and into an annular exhaust plenum 17. The annular slot 16 and the plenum 17 are defined by the gap between the top of the chamber's cylindrical side wall 15a (including the upper dielectric lining 19 on the wall) and the bottom of the circular chamber lid 20. The 360° circular symmetry and uniformity of the slot orifice 16 and the plenum 17 are typically important to achieving a uniform flow of process gases over the wafer so as to deposit a uniform film on the wafer.

From the exhaust plenum 17, the gases flow underneath a lateral extension portion 21 of the exhaust plenum 17, past a viewing port (not shown), through a downward-extending gas passage 23, past a vacuum shut-off valve 24 (whose body is integrated with the lower chamber wall 15a), and into the exhaust outlet 25 that connects to the external vacuum pump 50 through foreline 55.

The wafer support platter of the pedestal 12 (preferably aluminum, ceramic, or a combination thereof) is resistively-heated using an embedded single-loop embedded heater element configured to make two full turns in the form of parallel concentric circles. An outer portion of the heater element runs adjacent to a perimeter of the support platter, while an inner portion runs on the path of a concentric circle having a smaller radius. The wiring to the heater element passes through the stem of the pedestal 12.

Typically, any or all of the chamber lining, gas inlet manifold faceplate, and various other reactor hardware are made out of material such as aluminum, anodized aluminum, or a ceramic. An example of such a CVD apparatus is described in U.S. Pat. No. 5,558,717 entitled “CVD Processing Chamber”. U.S. Pat. No. 5,558,717 patent is assigned to Applied Materials, Inc., the assignee of the present invention, and is incorporated by reference for all purposes.

A lift mechanism and motor (not shown) raises and lowers the heated pedestal assembly 12 and its wafer lift pins 12b as wafers are transferred into and out of the body of the chamber by a robot blade (not shown) through an insertion/removal opening 26 in the side of the chamber 10. The motor raises and lowers pedestal 12 between a processing position 14 and a lower, wafer-loading position. The motor, valves or flow controllers connected to the supply lines 8, gas delivery system, throttle valve, RF power supply 44, and chamber and substrate heating systems are all controlled by a system controller 34 (FIG. 1A) over control lines 36, of which only some are shown. Controller 34 relies on feedback from optical sensors to determine the position of movable mechanical assemblies such as the throttle valve and susceptor which are moved by appropriate motors under the control of controller 34.

In one embodiment, the system controller includes a hard disk drive (memory 38), a floppy disk drive and a processor 37. The processor contains a single-board computer (SBC), analog and digital input/output boards, interface boards and stepper motor controller boards. Various parts of CVD system 10 conform to the Versa Modular European (VME) standard which defines board, card cage, and connector dimensions and types. The VME standard also defines the bus structure as having a 16-bit data bus and a 24-bit address bus.

System controller 34 controls all of the activities of the CVD machine. The system controller executes system control software, which is a computer program stored in a computer-readable medium such as a memory 38. Preferably, memory 38 is a hard disk drive, but memory 38 may also be other kinds of memory. The computer program includes sets of instructions that dictate the timing of introduction and evacuation of gases, the mixture of gases, chamber pressure, chamber temperature, RF power levels, susceptor position, and other parameters of a particular process. Other computer programs stored on other memory devices including, for example, a floppy disk or another appropriate drive, may also be used to operate controller 34.

The above reactor description is mainly for illustrative purposes, and other plasma CVD equipment such as electron cyclotron resonance (ECR) plasma CVD devices, induction coupled RF high density plasma CVD devices, or the like may be employed. Additionally, variations of the above-described system, such as variations in pedestal design, heater design, RF power frequencies, location of RF power connections and others are possible. For example, the wafer could be supported by a susceptor and heated by quartz lamps. The layer and method for forming such a layer of the present invention is not limited to any specific apparatus or to any specific plasma excitation method.

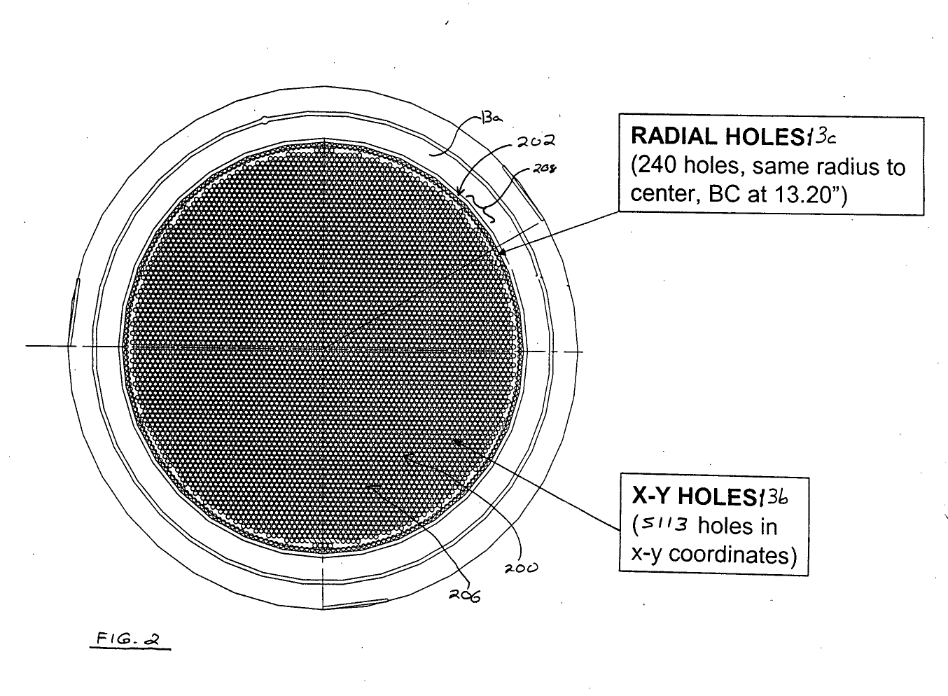

FIG. 2 shows a simplified plan view of the underside of one embodiment of a gas distribution showerhead in accordance with the present invention. Gas distribution faceplate 13a on the lower surface of showerhead 13 includes two distinct regions.

In a first, central region 200, a first set 206 of holes 13b are configured to deliver processing gases to form a layer of uniform thickness over central regions of a corresponding wafer surface. FIG. 2A is a simplified schematic view showing the arrangement of holes 13b of first set 206, in a non-concentric orientation assymmetric with respect to radius r of substantially circular faceplate 13a. This hole arrangement ensures a maximum density of holes and thus of the gases flowed through to the wafer surface.

In a second, peripheral region 202, a second set 208 of holes 13c are configured at a density to deliver processing gases to form the layer of a matching uniform thickness over wafer edge regions. FIG. 2B is a simplified schematic view showing the arrangement of holes 13c in a concentric orientation symmetric with respect to radius r of substantially circular faceplate 13a. This arrangement of holes ensures a flow of gases to the edge of the wafer that is homogenous, and results in formation of material at wafer edge regions that exhibits uniform character and properties. In one specific embodiment, the second set of holes 13c are oriented concentrically, with a ball circle (BC) of 13.20″. The dimension of the ball circle could vary, depending upon the size of the faceplate and the flow requirements.

In accordance with embodiments of the present invention, while the overall size of the substantially circular faceplate remains unchanged, owing to the extra concentric row of holes at the faceplate edge, the processed substrate experiences deposition as if from a larger diameter faceplate. Moreover, addition of the holes on the faceplate periphery makes plasma inside the chamber more uniform. This plasma uniformity in turn enhances the resulting uniformity in the property of deposited films, for example their thickness, refractive index (RI) and dielectric constant (k).

The size of holes in the second set can be the same as, or different from, the size of holes in the other part of the faceplate. This additional, concentrically-oriented row of holes can redistribute process gases to the wafer edge. The deposition rate on the wafer edge can be controlled independently. Therefore, chemical vapor deposition (CVD) of films exhibiting superior wafer center-to-edge uniformity can be achieved.

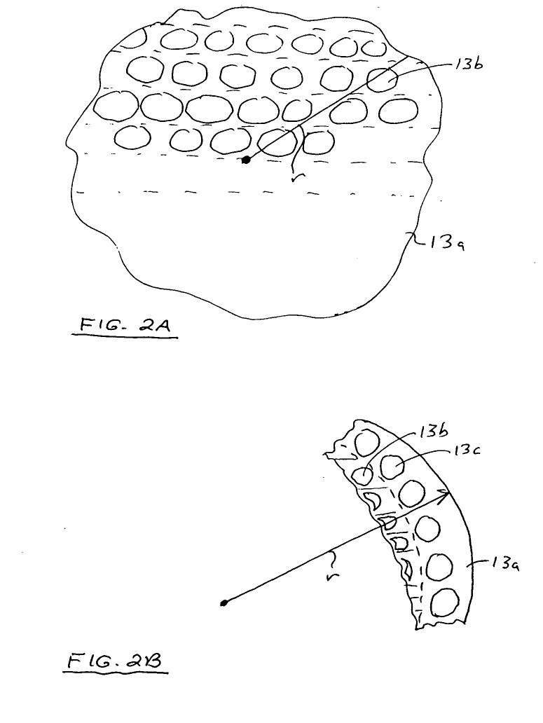

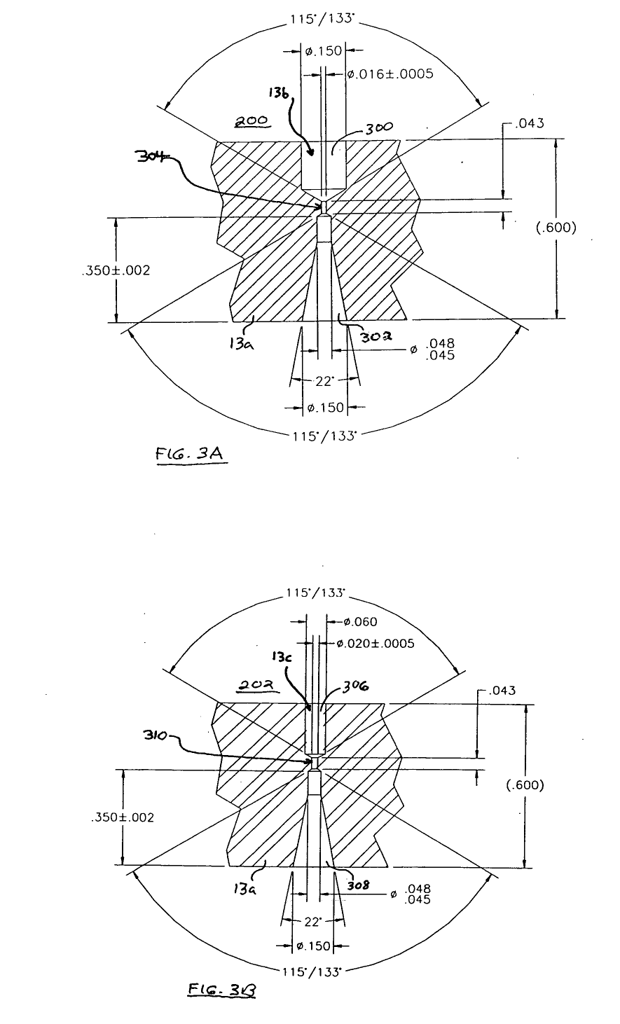

FIG. 3A shows a simplified cross-sectional view of a hole of the first set, of the apparatus shown in FIG. 2. This particular embodiment in accordance with the present invention includes five thousand one hundred and thirteen holes of the first type. Embodiments in accordance with the present invention are not limited to this or any other specific number of holes.

Holes 13b of this first set exhibit a counterbore 300 having a diameter of 0.150″ leading to an outlet bore 302 having a diameter of 0.045-0.048″, through a constriction or orifice 304 having a diameter of about 0.016+/−0.0005″ and a length of 0.043″. These holes 13b are not oriented concentrically, but rather according to rows defined within the X-Y plane of the showerhead. The number and dimensions of holes of the first type could vary, depending upon the size of the faceplate and the flow requirements.

FIG. 3B shows a simplified cross-sectional view of a hole 13c of the second set, of the apparatus shown in FIG. 2. This particular embodiment in accordance with the present invention includes two hundred and forty holes of the second type. This second set of holes 13c exhibit a counterbore 306 having a diameter of 0.060″ leading to an outlet bore 308 having a diameter of 0.045-0.048″, through a constriction or orifice 310 having a diameter of about 0.020+/−0.0005″ and a length of 0.043″. The number and dimensions of holes of the second type could vary, depending upon the size of the faceplate and the flow requirements.

As described above, utilization of a gas distribution showerhead/faceplate design in accordance with embodiments of the present invention improves uniformity of processing occurring at edges of a substrate. The following TABLE 1 illustrates several instances where the uniformity of characteristics of a material deposited by CVD utilizing the faceplate embodiment shown in FIG. 2 has improved over a conventional faceplate lacking the second set of concentrically-oriented orifices.

TABLE 1
CENTER-TO-EDGE UNIFORMITY OF CVD FILM

| | FACEPLATE LACKING | FACEPLATE INCLUDING |
|---|---|---|
| | CONCENTRICALLY- | CONCENTRICALLY- |
| DEPOSITED FILM | ARRANGED ORIFICES | ARRANGED ORIFICES |
| Applied Materials | Thickness Uniformity = 2.3% | Thickness Uniformity = 1.2% |
| BLOk ™ Nitrogen- | Refractive Index (RI) | Refractive Index (RI) Range = 0.019 |
| Containing Barrier Film | Range = 0.09 | |
| Applied Materials Black | Thickness Uniformity = 2.5% | Thickness Uniformity = 1.11% |
| Diamond ™ Carbon- | | |
| Containing Low K Film | | |
| (First Dep. Conditions) | | |
| Applied Materials Black | Thickness Uniformity = 5-10% | Thickness Uniformity = 1.5% |
| Diamond ™ Carbon- | | |
| Containing Low K Film | | |
| (Second Dep. Conditions) | | |

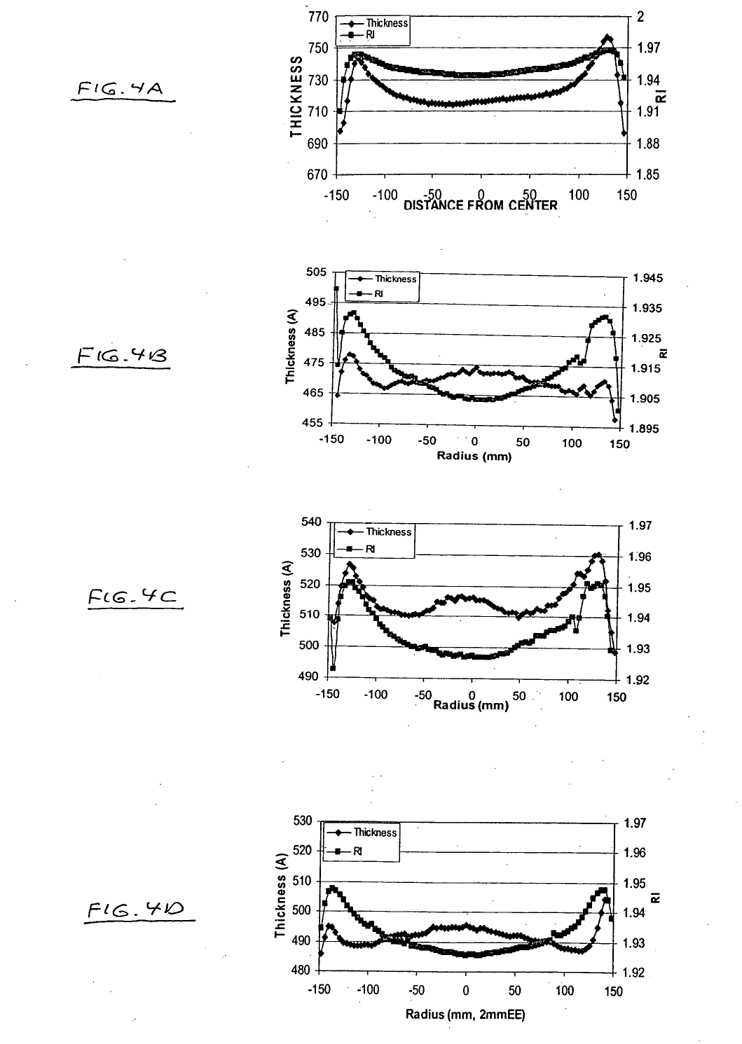

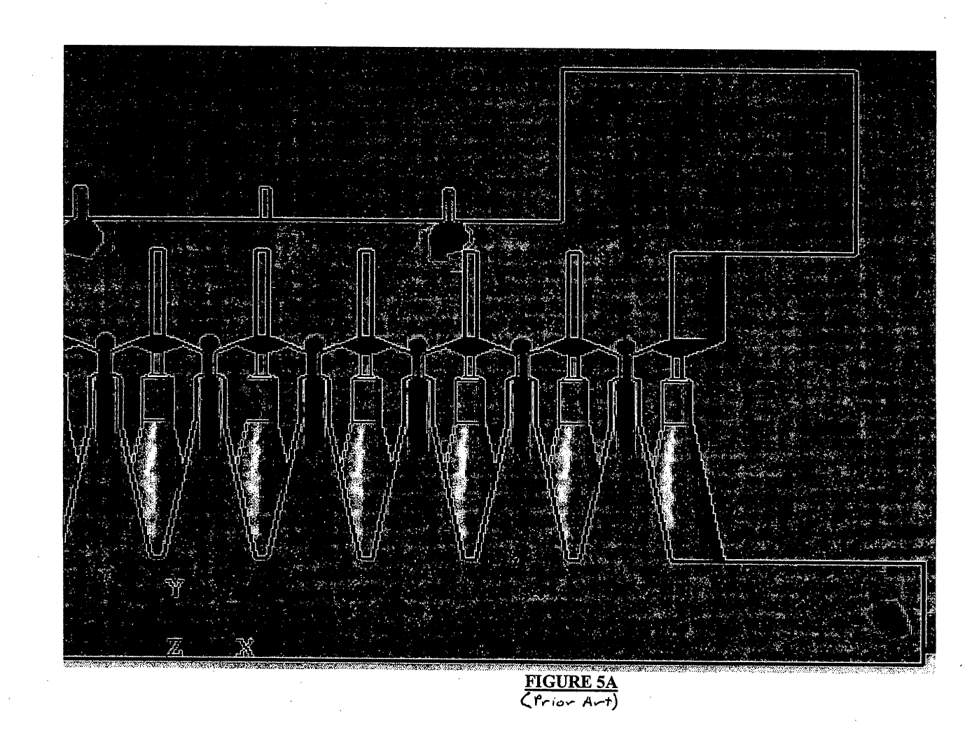

The following TABLE 2 and corresponding FIGS. 4A-D provide greater detail regarding the enhancement in uniformity characteristics of a BLOk™ nitrogen-containing barrier film, deposited utilizing a variety of different faceplate designs.

TABLE 2

| | FACEPLATE TYPE | | | |
|---|---|---|---|---|
| | | | Conventional + | Extended + |
| | Conventional | Extended | Radial Holes | Radial Holes |
| Number of XY Holes | 4,933 | 5,365 | 4,933 | 5,113 |
| Number of Radial Holes | 0 | 0 | 240 | 240 |
| Outermost Hole Ball Circle | 12.60″ | <=13.20″ | 13.08″ | 13.20″ |
| Figure Number | 4A | 4B | 4C | 4D |
| % Thickness Uniformity | 2.3 | 1.43 | 1.93 | 1.20 |
| Refractive Index (RI) Range | 0.090 | 0.026 | 0.037 | 0.019 |

TABLE 2 and FIGS. 4A-D show that extension of the area covered by the non-radially oriented holes, resulted in some improvement in uniformity of thickness and refractive index, as did the addition of radially oriented holes to the conventional faceplate design. The faceplate design combining both extension of the XY hole area and introduction of radially oriented holes, resulted in the greatest improvement in uniformity of characteristics of the deposited film.

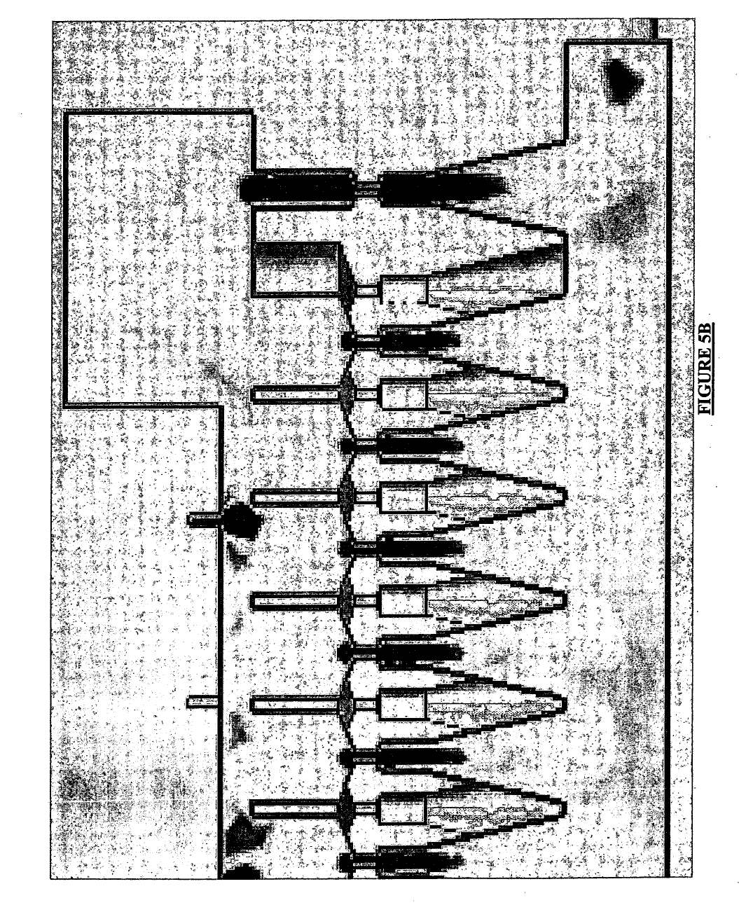

FIG. 5A shows a cross-sectional view illustrating axial velocity of a simulated flow of gas through a conventional faceplate comprising only the first set of holes. FIG. 5B shows a cross-sectional view illustrating axial velocity of a simulated flow of gas through an embodiment of a faceplate in accordance with the present invention featuring both the first and second set of holes. In the instant design, since the orifice size of the second set of holes is larger than the orifice size of the first set of holes, gas conductance of the second set of holes is larger, and the velocity is higher. Specifically, comparison of FIGS. 5A and 5B indicates that the axial velocity of gas flowed to edge regions of the wafer from the second hole set is about twice that flowed to center regions of the wafer from the first hole set. These simulation results reveal that the second set of holes bring extra gas flow to the edge of the wafer, and thus the amount of the flow could be controlled by the size of the orifices in the second set of holes.

Additional simulation regarding gas pressure indicates that for embodiments in accordance with the present invention featuring two sets of holes, the pressure drop observed across the first set of holes is very close to that observed across the second set of holes. The uniformity of this pressure drop across the first and second set of holes helps to establish a stable deposition condition on the wafer.

It should be understood that the inventions described herein can be employed in any substrate processing system which uses a showerhead to distribute process gas to the substrate. This includes not only CVD systems, but also etch and cleaning systems, to name just a few examples.

A variety of different gas types may be flowed through a showerhead exhibiting properties of the present invention. Embodiments in accordance with the present invention may distribute processing gases containing nitrogen or carbon as used in the deposition of nitrogen- or carbon-containing material. Embodiments in accordance with the present invention may also distribute gases containing fluorine or other highly reactive elements for use in cleaning residues from exposed surfaces within the chamber.

Embodiments in accordance with the present invention are not limited to the specific face plate designs described above. For example, the size, density, and number of radially-oriented holes may be varied according to the needs of a particular application.

Moreover, in accordance with still other embodiments of the present invention, gas may be flowed to the radially symmetric holes and to the non-radially symmetric holes through different pathways. In this manner, gas may be flowed to the center and edge regions of the faceplate at different pressures or velocities, thereby allowing the operator to exercise for more precise control over the deposition of material on substrate edge regions.

Although various embodiments which incorporate teachings of the present invention have been shown and described in detail herein, those skilled in the art can readily devise many other varied embodiments that still incorporate these teachings. For example, while the specific embodiment described above features a single row of concentrically-oriented holes on the faceplate periphery, the present invention is not limited to this configuration. Alternative embodiments could utilize more than one such row of holes of the second type and remain within the scope of the present invention.

While the above is a complete description of specific embodiments of the present invention, various modifications, variations, and alternatives may be employed. These equivalents and alternatives are included within the scope of the present invention. Therefore, the scope of this invention is not limited to the embodiments described, but is defined by the following claims and their full scope of equivalents.

1. An apparatus comprising:
walls enclosing a process chamber;
a wafer susceptor positioned within the chamber;
a first exhaust conduit in fluid communication with the chamber; and
a processing gas source in fluid communication with the chamber through a substantially circular gas distribution showerhead, the gas distribution showerhead comprising;
a first set of holes positioned in a central showerhead region assymmetric to a radius of the showerhead, and
a second set of holes positioned in a peripheral showerhead region symmetric to the radius.

2. The apparatus of claim 1 wherein the gas distribution showerhead is configured to deliver gas to the surface of a substrate having a diameter of 300 mm, the first set of holes numbering about 5000, and the second set of holes numbering about 240.

3. The apparatus of claim 1 wherein the first and second set of holes comprise an inlet bore in fluid communication with an outlet bore through an orifice having a width smaller than the inlet bore and the outlet bore.

4. The apparatus of claim 3 wherein an orifice of the first set of holes has a diameter of about 0.016″, and an orifice of the second set of holes has a diameter of about 0.020″.

5. The apparatus of claim 3 wherein the second set of holes are arranged in a single row having centers at a ball circle with respect to a wafer center.

6. The apparatus of claim 1 further comprising a first gas pathway leading from a gas source to the first set of holes, and a second gas pathway leading from the gas source to the second set of holes.

7. The apparatus of claim 1 wherein the second set of holes is configured to flow to edge portions of a wafer, gas having an axial velocity of approximately twice an axial velocity exhibited by gas flowed through the first set of holes.

8. A method for depositing material on a semiconductor substrate, the method comprising:
flowing processing gases to a central portion of a substrate through a first set of non-radially symmetrical holes present in a central portion of a substantially circular gas distribution faceplate; and
flowing the processing gases to an edge portion of the substrate through a second set of radially symmetrical holes present in a peripheral portion of the substantially circular gas distribution faceplate.

9. The method of claim 8 wherein the processing gases are flowed simultanously through the first and second set of holes.

10. The method of claim 8 wherein flowing the processing gases to the edge portion comprises flowing additional volumes of processing gases to compensate for the flow of gases away from the edge portion.

11. The method of claim 8 wherein flowing the processing gases produces deposition of a solid material on the substrate.

12. The method of claim 8 wherein flowing the processing gases through the first and second holes improves uniformity of at least one of thickness, refractive index, and dielectric constant, exhibited by the deposited material.

13. The method of claim 8 wherein the second set of holes is configured to flow to edge portions of a wafer, gas having an axial velocity approximately twice an axial velocity exhibited by gas flowed through the first set of holes.

14. The method of claim 12 wherein flowing the processing gases comprises flowing carbon-containing processing gases to accomplish deposition of a carbon-containing material.

15. The method of claim 14 wherein flowing the processing gases accomplishes deposition of carbon-containing silicon oxide low K dielectric layer exhibiting a thickness uniformity of 1.5% or less.

16. The method of claim 12 wherein flowing the processing gases comprises flowing nitrogen-containing processing gases to accomplish deposition of a nitrogen-containing material.

17. The method of claim 16 wherein flowing the processing gases accomplishes deposition of nitrogen-containing silicon oxide barrier layer exhibiting a range of variation of refractive index of 0.02 or less.

18. The method of claim 8 wherein flowing the processing gases comprise flowing fluorine-containing processing gases.

19. A circular gas distribution showerhead comprising a faceplate defining a first set of holes positioned in a central region asymmetric to a radius of the faceplate, and a second set of holes positioned in a peripheral region symmetric to the radius.

20. The showerhead of claim 19 wherein the first and second set of holes comprise an inlet bore in fluid communication with an outlet bore through an orifice having a width smaller than the inlet bore and the outlet bore.

21. The showerhead of claim 20 wherein a diameter of the orifice of the first set of holes is smaller than a diameter of the orifice of the second set of holes.
